(19) United States
(12) Patent Application Publication
(10) Pub. No.: US 2016/0315179 A1
(43) Pub. Date: Oct. 27, 2016

(54) COMPOUND SEMICONDUCTOR DEVICE AND METHOD OF MANUFACTURING THE SAME

(71) Applicant: FUJITSU LIMITED, Kawasaki-shi (JP)

(72) Inventors: Masato Nishimori, Atsugi (JP); Tadahiro Imada, Kawasaki (JP); LEI ZHU, Atsugi (JP)

(73) Assignee: FUJITSU LIMITED, Kawasaki-shI (JP)

(21) Appl. No.: 15/084,765

(22) Filed: Mar. 30, 2016

(30) Foreign Application Priority Data
Apr. 21, 2015 (JP) 2015-087119

(51) Int. Cl. H01L 29/778; H01L 29/20; H01L 29/205; H01L 29/15; H02M 7/5387; H01L 29/66; H01L 21/02; H03F 3/21; H02M 1/08; H01L 29/207; H01L 29/36

(52) U.S. Cl. CPC H01L 29/7783; H01L 29/207; H01L 29/2003; H01L 29/205; H01L 29/155; H01L 29/36; H01L 29/66462; H01L 21/02458; H01L 21/02507; H01L 21/0254; H03F 3/21; H02M 1/08; H02M 7/5387; H01L 21/02378; H01L 21/02381; H01L 21/0242; H01L 21/02389; H01L 21/02414; H03F 1/3205

(57) ABSTRACT

A compound semiconductor device includes: a substrate; a nucleation layer over the substrate; a first buffer layer over the nucleation layer; a second buffer layer between the nucleation layer and the first buffer layer, the second buffer layer containing an acceptor impurity element or a donor impurity element at a higher concentration than the first buffer layer; a carrier transit layer in contact with the first buffer layer; a carrier supply layer over the carrier transit layer; and a gate electrode, a source electrode, and a drain electrode above the carrier supply layer.

### CROSS-REFERENCE TO RELATED APPLICATION

This application is based upon and claims the benefit of priority of the prior Japanese Patent Application No. 2015-087119, filed on Apr. 21, 2015, the entire contents of which are incorporated herein by reference.

### FIELD

The embodiments discussed herein are directed to a compound semiconductor device, a method of manufacturing the same, and the like.

### BACKGROUND

A nitride semiconductor has characteristics such as a high saturation electron velocity and a wide band gap. Accordingly, various studies have been made on application of nitride semiconductor to high-withstand voltage and high-output semiconductor devices by utilizing these characteristics. For example, the band gap of GaN as one of nitride semiconductors is 3.4 eV, which is larger than the band gap (1.1 eV) of Si and the band gap (1.4 eV) of GaAs. Thus, GaN has high breakdown electric field intensity and holds great promise as a material of a semiconductor device for power supplies which obtain a high withstand voltage and high output.

With respect to semiconductor devices including nitride semiconductor, various reports have been made on field effect transistors, particularly high electron mobility transistors (HEMT). For example, as a GaN-based HEMT, an AlGaN/GaN-HEMT is attracting attention, in which GaN is used for a carrier transit layer (channel layer) and AlGaN is used for a carrier supply layer (barrier layer). A distortion caused by a lattice mismatch between GaN and AlGaN occurs in the AlGaN in the AlGaN/GaN-HEMT. Two-dimensional electron gas (2 DEG) at a high concentration is obtained due to piezoelectric polarization generated by the distortion and autonomous polarization of the AlGaN. Thus, the AlGaN/GaN-HEMT is expected as a high-withstand voltage power device preferred for transmitting power amplifiers of a base station, high-efficiency switch elements, electric vehicles, and the like.

However, when a high voltage is applied to a drain electrode, a leak current may flow between the drain electrode and a substrate, or a sufficient breakdown withstand voltage may not be obtained. They are significant particularly when Si is used as a material for a substrate for the purpose of cost reduction. Although a technique to use a buffer layer having a superlattice structure containing carbon has been proposed, it cannot achieve a sufficient withstand voltage.

Patent Literature 1: Japanese Laid-Open Patent Publication No. 2008-171843

Patent Literature 2: Japanese Laid-Open Patent Publication No. 2013-30725

### SUMMARY

According to an aspect of the embodiments, a compound semiconductor device includes: a substrate; a nucleation layer over the substrate; a first buffer layer over the nucleation layer; a second buffer layer between the nucleation layer and the first buffer layer, the second buffer layer containing an acceptor impurity element or a donor impurity element at a higher concentration than the first buffer layer; a carrier transit layer in contact with the first buffer layer; a carrier supply layer over the carrier transit layer; and a gate electrode, a source electrode, and a drain electrode above the carrier supply layer.

According to another aspect of the embodiments, a method of manufacturing a compound semiconductor device includes: forming a nucleation layer over a substrate; forming a first buffer layer over the nucleation layer; forming a second buffer layer between the nucleation layer and the first buffer layer, the second buffer layer containing an acceptor impurity element or a donor impurity element at a higher concentration than the first buffer layer; forming a carrier transit layer in contact with the first buffer layer; forming a carrier supply layer over the carrier transit layer; and forming a gate electrode, a source electrode, and a drain electrode above the carrier supply layer.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view illustrating a structure of a compound semiconductor device according to a first embodiment;

FIG. 2 is a diagram illustrating a band structure of the compound semiconductor according to the first embodiment;

FIG. 3 is a cross-sectional view illustrating a structure of a reference example;

FIG. 4 is a diagram illustrating a band structure of the reference example;

FIG. 5A is a cross-sectional view illustrating a model for simulation;

FIG. 5B is a diagram illustrating a relation between a voltage and a leak current;

FIG. 5C is a diagram illustrating a band structure of the model;

FIG. 6A to FIG. 6C are cross-sectional views illustrating a method of manufacturing the compound semiconductor device according to the first embodiment in order of steps;

FIG. 7 is a cross-sectional view illustrating a structure of a compound semiconductor device according to a second embodiment;

FIG. 8 is a view illustrating a band structure of the compound semiconductor device according to the second embodiment;

FIG. 9 is a cross-sectional view illustrating a structure of a compound semiconductor device according to a third embodiment;

FIG. 10 is a view illustrating a band structure of the compound semiconductor device according to the third embodiment;

FIG. 11 is a cross-sectional view illustrating a structure of a compound semiconductor device according to a fourth embodiment;

FIG. 12 is a diagram illustrating a relation between a concentration of p-type carrier and a thickness of a depletion layer generated in a lower buffer layer;

FIG. 13A and FIG. 13B are views illustrating change of carrier in a case where activation energy of impurity contained in a lower buffer layer is low;

FIG. 14A and FIG. 14B are views illustrating change of carrier in a case where activation energy of impurity contained in a lower buffer layer is high;

FIG. 15 is a cross-sectional view illustrating a nucleation layer doped with an impurity;

FIG. 16 is a cross-sectional view illustrating an upper buffer layer of superlattice structure;

FIG. 17 is a view illustrating a discrete package according to a fifth embodiment;

FIG. 18 is a wiring diagram illustrating a PFC circuit according to the sixth embodiment;

FIG. 19 is a wiring diagram illustrating a power supply apparatus according to a seventh embodiment;

FIG. 20 is a wiring diagram illustrating an amplifier according to an eighth embodiment.

### DESCRIPTION OF EMBODIMENTS

Hereinafter, embodiments will be explained specifically with reference to accompanying drawings.

### First Embodiment

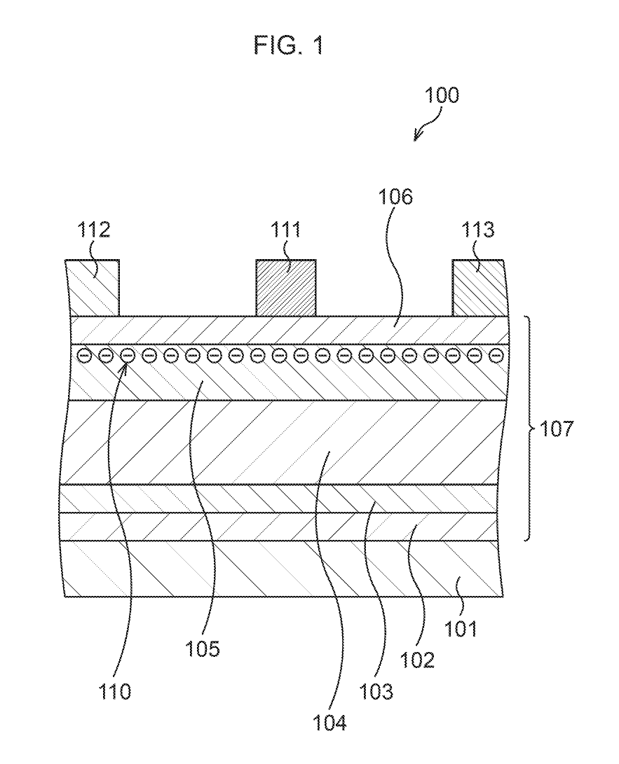

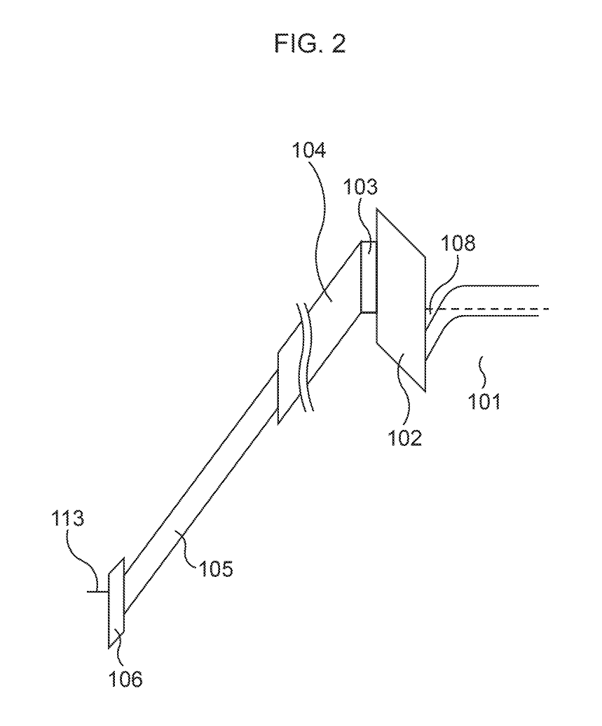

First, a first embodiment will be explained. The first embodiment is an example of a high electron mobility transistor (HEMT). FIG. 1 is a cross-sectional view illustrating a structure of a compound semiconductor device according to the first embodiment. FIG. 2 is a diagram illustrating a band structure of the compound semiconductor according to the first embodiment.

The compound semiconductor device 100 according to the first embodiment includes, as illustrated in FIG. 1, a substrate 101, a nucleation layer 102 over the substrate 101, a lower buffer layer 103 over the nucleation layer 102, and an upper buffer layer 104 over the lower buffer layer 103. The compound semiconductor device 100 includes a carrier transit layer (channel layer) 105 and a carrier supply layer 106 over the upper buffer layer 104, and a gate electrode 111, a source electrode 112, and a drain electrode 113 above the carrier transit layer 105 and the carrier supply layer 106. The lower buffer layer 103 contains an acceptor impurity element at a higher concentration than the upper buffer layer 104. The lower buffer layer 103 is an example of a second buffer layer, and the upper buffer layer 104 is an example of a first buffer layer.

The substrate 101 is, for example, a Si substrate, a SiC substrate, a sapphire substrate, or a GaN substrate. The nucleation layer 102 is, for example, an AlN layer having a thickness of about 200 nm. The lower buffer layer 103 is, for example, an Al_{0.2}Ga_{0.8}N layer (p-type AlGaN layer) having a thickness of about 200 nm and containing Mg at a concentration of about 5×10¹⁹ cm⁻³. Mg is an example of an acceptor impurity. The upper buffer layer 104 is, for example, an Al_{0.2}Ga_{0.8}N layer (i-type AlGaN layer) having a thickness of about 100 nm to 600 nm and being not intentionally doped with impurity. The carrier transit layer 105 is, for example, a GaN layer (i-type GaN layer) having a thickness of about 1 μm and being not intentionally doped with impurity. The carrier supply layer 106 is, for example, an Al_{0.2}Ga_{0.8}N layer (n-type AlGaN layer) having a thickness of about 20 nm and containing a donor impurity such as Si or an Al_{0.2}Ga_{0.8}N layer (i-type AlGaN layer) having a thickness of about 20 nm and being not intentionally doped with impurity. The gate electrode 111 includes, for example, a Ni film and an Au film over the Ni film, and the source electrode 112 and the drain electrode 113 include, for example, a Ti film and an Al film over the Ti film. The gate electrode 111 is in Schottky contact with a layered structure 107 of the nucleation layer 102, the lower buffer layer 103, the upper buffer layer 104, the carrier transit layer 105, and the carrier supply layer 106. The source electrode 112 and the drain electrode 113 are in ohmic contact with the layered structure 107.

In the first embodiment, since the lower buffer layer 103 contains an acceptor impurity element at a higher concentration than the upper buffer layer 104, the potential of the nucleation layer 102 is high on the lower buffer layer 103 side, as illustrated in FIG. 2. Accordingly, the position to be depleted by application of a high voltage to the drain electrode 113 is an upper portion of the lower buffer layer 103, and depletion of the nucleation layer 102 is suppressed. Therefore, even when an electron inversion layer 108 is formed on the surface of the substrate 101, it is difficult for a strong electric field to be applied to the nucleation layer 102, and generation of tunnel current accompanying application of strong electric field is suppressed.

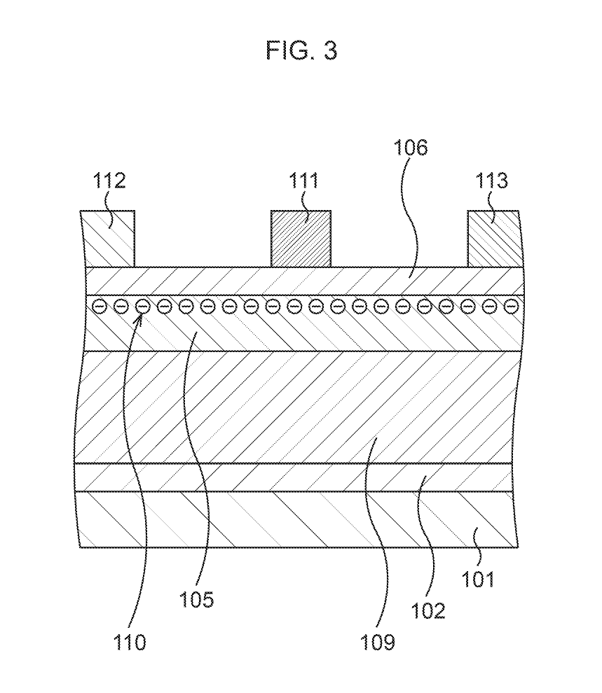

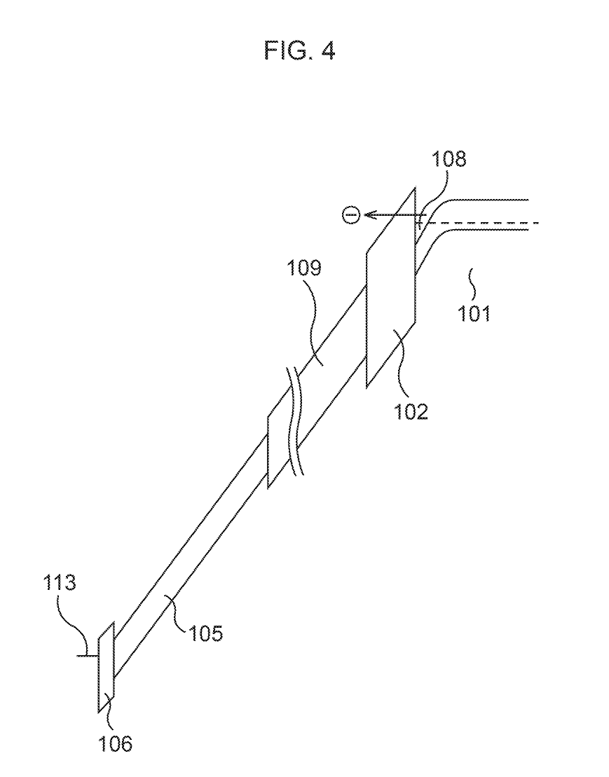

In a reference example illustrated in FIG. 3, an Al_{0.2}Ga_{0.8}N layer (i-type AlGaN layer) having a thickness of about 300 nm to 800 nm and being not intentionally doped with impurity is included as a buffer layer 109, instead of the lower buffer layer 103 and the upper buffer layer 104. In this reference example, as illustrated in FIG. 4, the nucleation layer 102 is depleted when a high voltage is applied to the drain electrode 113. Therefore, when the electron inversion layer 108 is formed on the surface of the substrate 101, a strong electric field is applied to the nucleation layer 102, and a tunnel current accompanying the application of the strong electric field is generated.

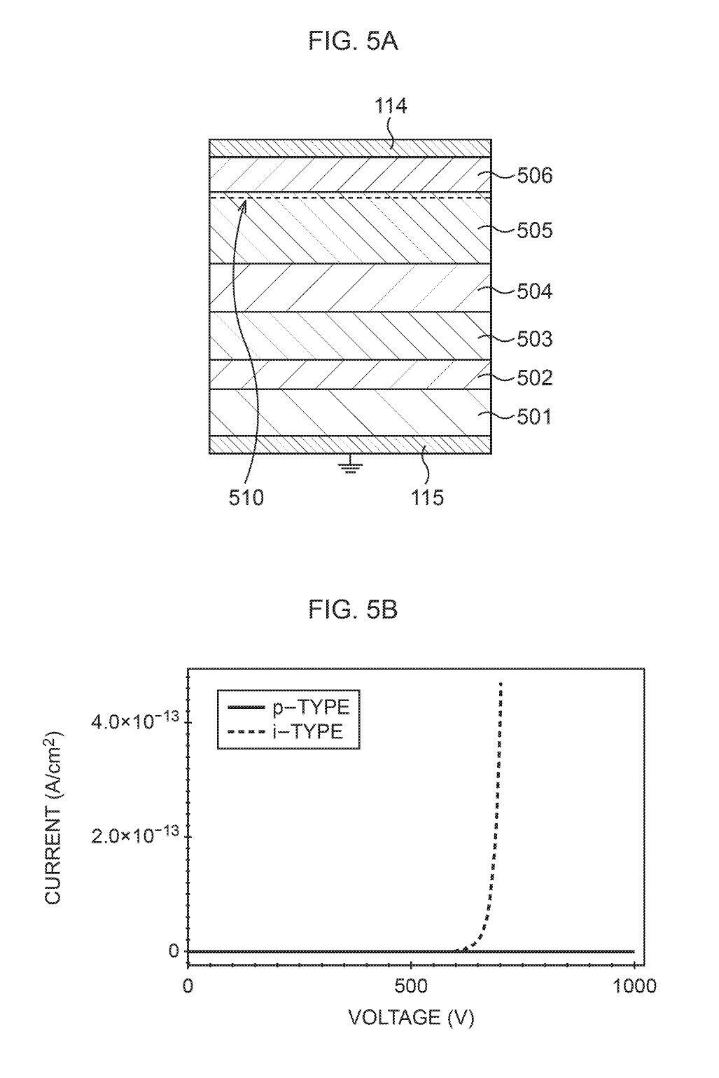

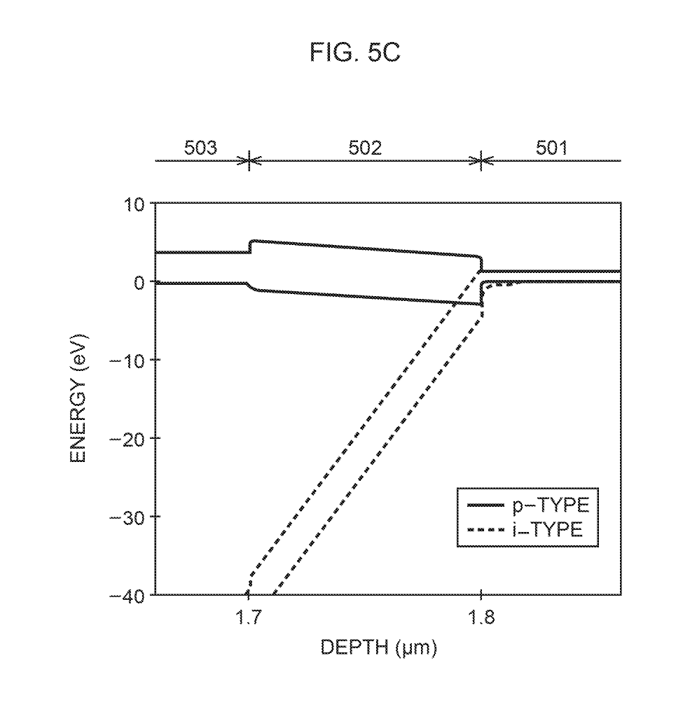

Here, simulations related to the first embodiment carried out by the present inventor will be explained. In the simulations, a technology CAD (technology computer aided design: TCAD) was used to calculate a withstand voltage and a band structure in a model illustrated in FIG. 5A. In the model, a substrate 501 is a Si substrate having a thickness of 1000 nm, a nucleation layer 502 is an AlN layer having a thickness of 100 nm, and a lower buffer layer 503 is a p-type Al_{0.2}Ga_{0.8}N layer or an i-type Al_{0.2}Ga_{0.8}N layer having a thickness of 200 nm. An upper buffer layer 504 is an i-type Al_{0.2}Ga_{0.8}N layer having a thickness of 500 nm, a carrier transit layer (channel layer) 505 is a GaN layer having a thickness of 1000 nm, and a carrier supply layer 506 is an i-type Al_{0.2}Ga_{0.8}N layer having a thickness of 20 nm. A 2 DEG 510 exists in the vicinity of the interface of the carrier transit layer 505 to the carrier supply layer 506. An ohmic electrode 115 is provided on a lower surface of the substrate 501, and an ohmic electrode 114 is provided on an upper surface of the carrier supply layer 506. The concentration of the acceptor impurity element of the lower buffer layer 503 when the lower buffer layer 503 is the p-type Al_{0.2}Ga_{0.8}N layer is 1×10¹⁹ cm⁻³.

In the simulation of the withstand voltage, the ohmic electrode 115 was grounded, the voltage to be applied to the ohmic electrode 114 was changed, and the current flowing between the ohmic electrode 114 and the ohmic electrode 115 was calculated. Results thereof are illustrated in FIG. 5B. In the simulation of the band structure, the band structure when 700 V is applied to the ohmic electrode 114 was calculated. Results thereof are illustrated in FIG. 5C. The horizontal axis of FIG. 5C is the depth from the surface of the carrier supply layer 506.

As illustrated in FIG. 5B, when the lower buffer layer 503 is a p-type Al_{0.2}Ga_{0.8}N layer, the leak current barely flows even when a voltage of 1000 V or higher is applied, but when the lower buffer layer 503 is an i-type Al_{0.2}Ga_{0.8}N layer, the leak current increases largely by about 600 V. Further, as illustrated in FIG. 5C, when the lower buffer layer 503 is a p-type AlGaN layer as illustrated in the first embodiment, the change of the band of the nucleation layer 502 is moderate even when a voltage of 700 V is applied. This indicates that it is difficult for tunnel current to flow. On the other hand, when the lower buffer layer 503 is an i-type AlGaN layer, the change of the band of the nucleation layer 502 is abrupt when the voltage of 700 V is applied. This indicates that it is easy for tunnel current to flow.

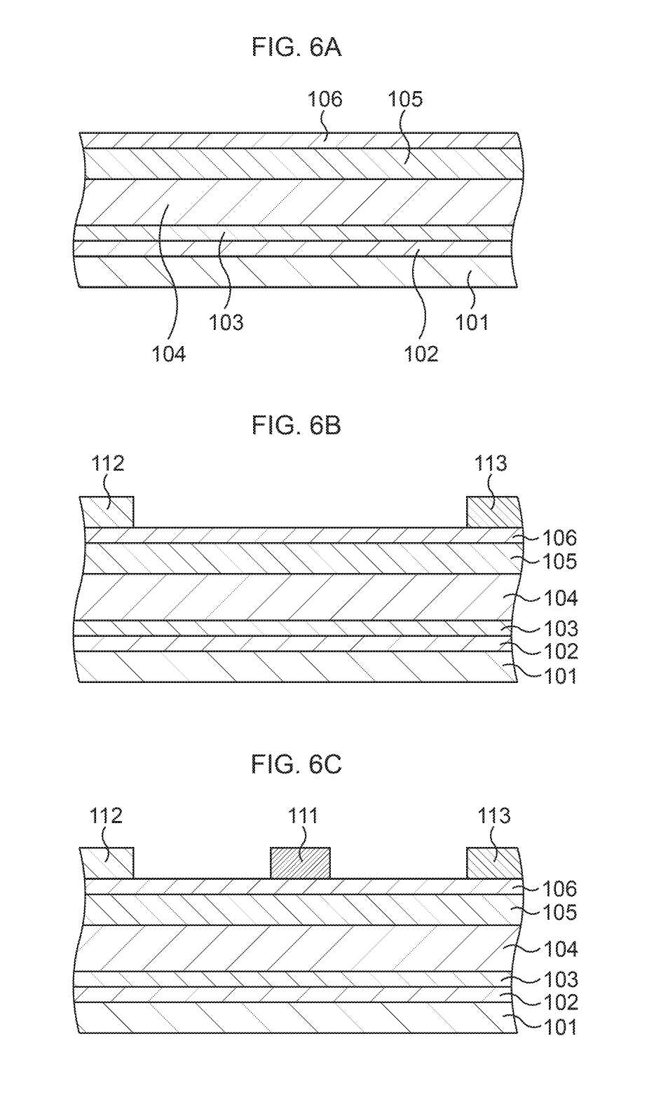

Next, a method of manufacturing the compound semiconductor device according to the first embodiment will be explained. FIG. 6A to FIG. 6C are cross-sectional views illustrating the method of manufacturing the compound semiconductor device according to the first embodiment in order of steps.

First, as illustrated in FIG. 6A, the nucleation layer 102, the lower buffer layer 103, the upper buffer layer 104, the carrier transit layer 105, and the carrier supply layer 106 are formed over the substrate 101. The nucleation layer 102, the lower buffer layer 103, the upper buffer layer 104, the carrier transit layer 105, and the carrier supply layer 106 may be formed by, for example, a crystal growth method such as a metal organic chemical vapor deposition (MOCVD) method or a molecular beam epitaxy (MBE) method. The growth temperature is about 1000° C., and the growth pressure is about 50 mbar. A mixed gas of a trimethylaluminium (TMA) gas, a trimethylgallium (TMG) gas, and an ammonia (NH₃) gas is used as a source gas, for example. The presence of supply of the TMA gas and the TMG gas and the flow rate thereof are controlled appropriately in accordance with a compound semiconductor layer to be formed. Cyclopentadienyl magnesium (CpMg) may be used as a material of magnesium (Mg) contained as acceptor impurity in the lower buffer layer 103, for example. Silane (SiH₄) may be used as a material of silicon (Si) contained in the carrier supply layer 106, for example.

Then, an element isolation region is formed, which defines an element region in the layered structure 107 of the nucleation layer 102, the lower buffer layer 103, the upper buffer layer 104, the carrier transit layer 105, and the carrier supply layer 106. In formation of the element isolation regions, for example, a pattern of a photoresist exposing a region where the element isolation region is to be formed is formed over the carrier supply layer 106, and this pattern is used as a mask to inject ions of Ar or the like. Dry etching using a chlorine-based gas with this pattern being an etching mask may be performed instead of the ion-injection. Thereafter, as illustrated in FIG. 6B, the source electrode 112 and the drain electrode 113 are formed above the carrier supply layer 106 in the element region. The source electrode 112 and the drain electrode 113 may be formed by, for example, a lift-off method. Specifically, a pattern of a photoresist exposing a region where the source electrode 112 is to be formed and a region where the drain electrode 113 is to be formed and covering the other region is formed, a metal film is formed by a vapor deposition method with this pattern being a growth mask, and this pattern is removed together with the metal film located thereon. In formation of the metal film, for example, a Ti film having a thickness of about 100 nm is formed, and an Al film having a thickness of about 300 nm is formed thereon. Then, a heat treatment such as rapid thermal annealing (RTA) is performed, for example, in an N₂ gas atmosphere at 400° C. to 800° C. (for example, 600° C.), so as to obtain ohmic contact. Further, as illustrated in FIG. 6C, the gate electrode 111 is formed above the carrier supply layer 106 between the source electrode 112 and the drain electrode 113. The gate electrode 111 may be formed by, for example, a lift-off method. Specifically, a pattern of a photoresist exposing a region where the gate electrode 111 is to be formed is formed, a metal film is formed by a vapor deposition method with this pattern being a growth mask, and this pattern is removed together with the metal film located thereon. In formation of the metal film, for example, an Ni film having a thickness of about 50 nm is formed, and an Au film having a thickness of about 300 nm is formed thereon.

Then a protection film, wirings, and so on are formed as necessary, thereby completing the compound semiconductor device.

### Second Embodiment

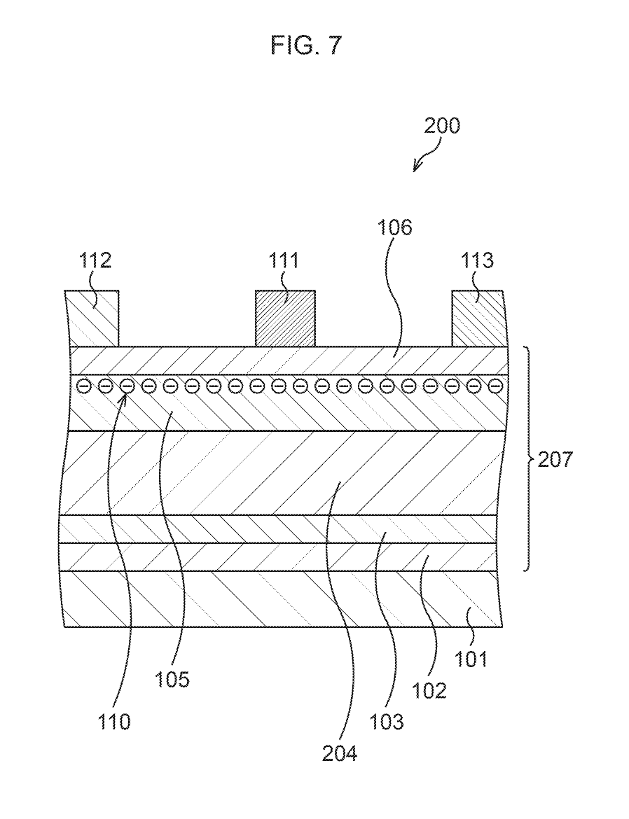

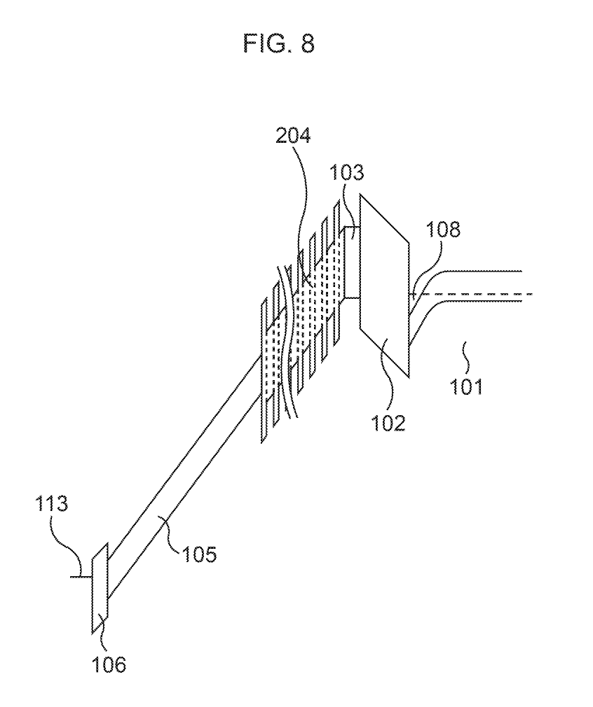

Next, a second embodiment will be explained. The second embodiment is an example of a high electron mobility transistor (HEMT). FIG. 7 is a cross-sectional view illustrating a structure of a compound semiconductor device according to the second embodiment. FIG. 8 is a view illustrating a band structure of the compound semiconductor device according to the second embodiment.

The compound semiconductor device 200 according to the second embodiment includes, as illustrated in FIG. 7, an upper buffer layer 204 having a superlattice structure instead of the upper buffer layer 104 in the first embodiment. The lower buffer layer 103 contains an acceptor impurity element at a higher concentration than the upper buffer layer 204. The upper buffer layer 204 includes a laminate made by repeating formation of an AlN layer having a thickness of about 5 nm and a GaN layer having a thickness of about 20 nm for about 100 cycles. A layered structure 207 includes the nucleation layer 102, the lower buffer layer 103, the upper buffer layer 204, the carrier transit layer 105, and the carrier supply layer 106. The other structure is the same as that of the first embodiment.

In the second embodiment, since the lower buffer layer 103 contains an acceptor impurity element at a higher concentration than the upper buffer layer 204, the potential of the nucleation layer 102 is high on the lower buffer layer 103 side, as illustrated in FIG. 8. Accordingly, the position to be depleted by application of a high voltage to the drain electrode 113 is an upper portion of the lower buffer layer 103, and depletion of the nucleation layer 102 is suppressed. Therefore, even when an electron inversion layer 108 is formed on the surface of the substrate 101, it is difficult for a strong electric field to be applied to the nucleation layer 102, and generation of tunnel current accompanying application of strong electric field is suppressed. That is, the same effect as that of the first embodiment may be obtained.

Further, the upper buffer layer 204 of the superlattice structure may alleviate a lattice distortion more than the upper buffer layer 104 of AlGaN, and thus the layered structure 207, which includes the upper buffer layer 204, may be formed thicker than the layered structure 107. Therefore, a higher withstand voltage may be obtained.

When the compound semiconductor device 200 is manufactured, the upper buffer layer 204 may be formed instead of the upper buffer layer 104 by the crystal growth method such as an MOCVD method or an MBE method.

### Third Embodiment

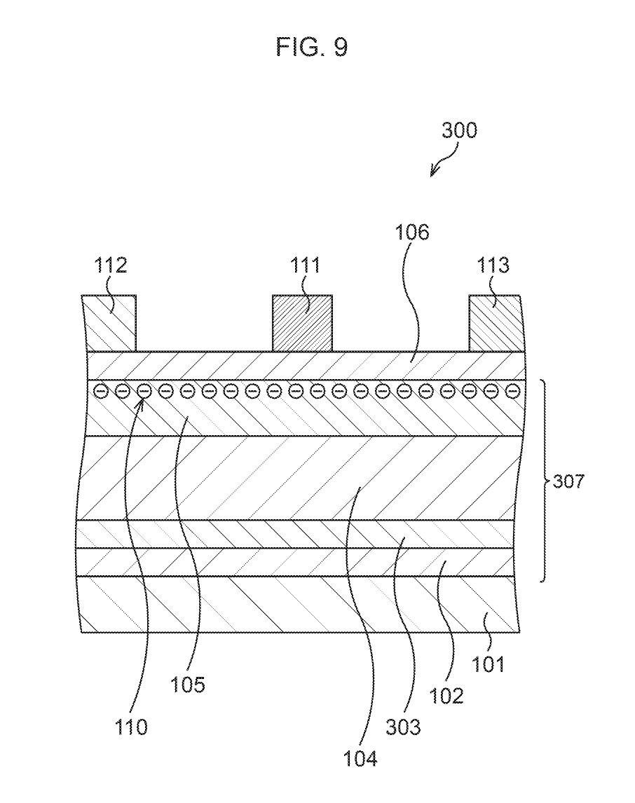

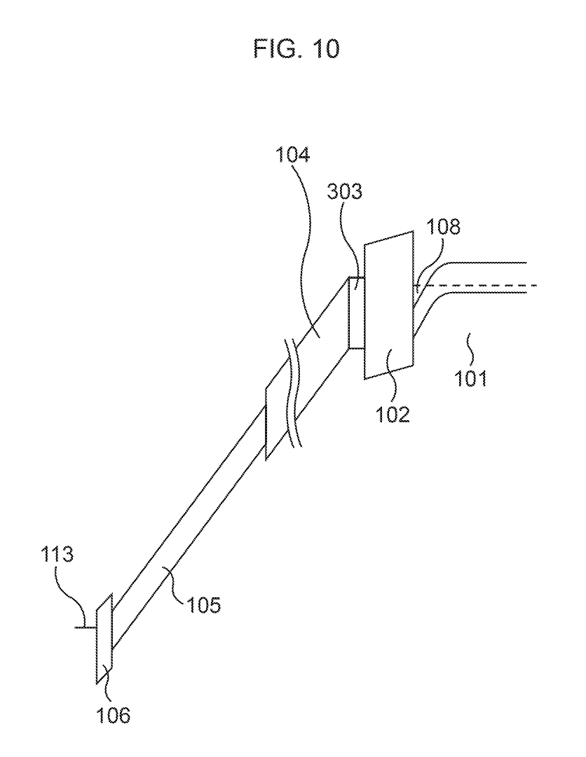

Next, a third embodiment will be explained. The third embodiment is an example of a high electron mobility transistor (HEMT). FIG. 9 is a cross-sectional view illustrating a structure of a compound semiconductor device according to the third embodiment. FIG. 10 is a view illustrating a band structure of the compound semiconductor device according to the third embodiment.

The compound semiconductor device 300 according to the third embodiment includes, as illustrated in FIG. 9, a lower buffer layer 303 containing a donor impurity element at a higher concentration than the upper buffer layer 104 instead of the lower buffer layer 103 in the first embodiment. The lower buffer layer 303 is, for example, an Al_{0.2}Ga_{0.8}N layer (n-type AlGaN layer) having a thickness of about 200 nm and containing Si at a concentration of about 1×10¹⁹ cm⁻³. Si is an example of a donor impurity. A layered structure 307 includes the nucleation layer 102, the lower buffer layer 303, the upper buffer layer 104, the carrier transit layer 105, and the carrier supply layer 106. The other structure is the same as that of the first embodiment.

In the third embodiment, since the lower buffer layer 303 contains a donor impurity element at a higher concentration than the upper buffer layer 104, the potential of the nucleation layer 102 is high on the lower buffer layer 303 side, as illustrated in FIG. 10. Accordingly, the position to be depleted by application of a high voltage to the drain electrode 113 is an upper portion of the lower buffer layer 303, and depletion of the nucleation layer 102 is suppressed. Therefore, even when an electron inversion layer 108 is formed on the surface of the substrate 101, it is difficult for a strong electric field to be applied to the nucleation layer 102, and generation of tunnel current accompanying application of strong electric field is suppressed. That is, the same effect as that of the first embodiment may be obtained.

For manufacturing the compound semiconductor device 300, the lower buffer layer 303 may be formed instead of the lower buffer layer 103 by a crystal growth method such as an MOCVD method or an MBE method.

### Fourth Embodiment

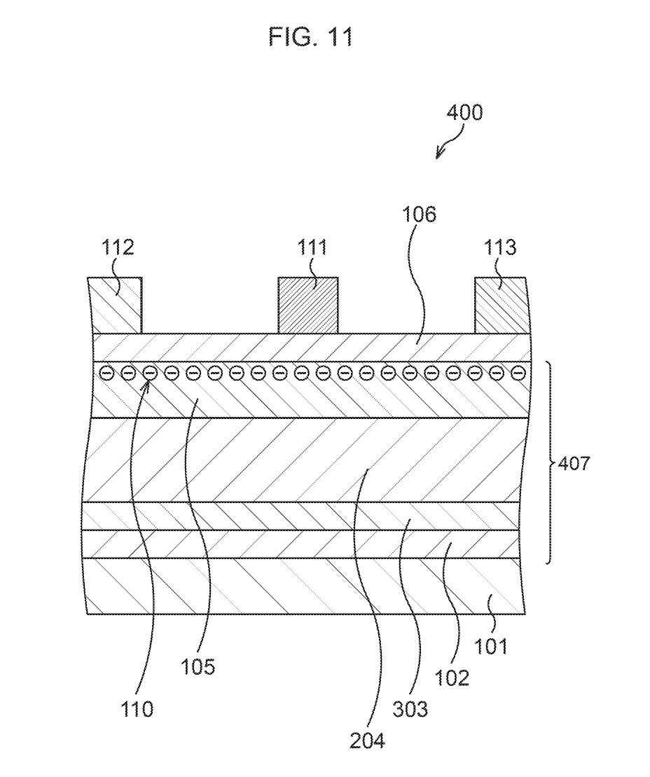

Next, a fourth embodiment will be explained. The fourth embodiment is an example of a high electron mobility transistor (HEMT). FIG. 11 is a cross-sectional view illustrating a structure of a compound semiconductor device according to the fourth embodiment.

The compound semiconductor device 400 according to the fourth embodiment includes, as illustrated in FIG. 11, the lower buffer layer 303 and the upper buffer layer 204 instead of the lower buffer layer 103 and the upper buffer layer 104 in the first embodiment, respectively. A layered structure 407 includes the nucleation layer 102, the lower buffer layer 303, the upper buffer layer 204, the carrier transit layer 105, and the carrier supply layer 106. The other structure is the same as that of the first embodiment.

According to the fourth embodiment, the same effects as those of the second embodiment and the third embodiment may be obtained.

A thickness of a lower buffer layer is not particularly limited, and is preferably 200 nm or less. In general, the thicker a compound semiconductor layer is formed, the easier it may be cracked due to the influence of a lattice distortion or the like. On the other hand, although depending on the usage, sufficient effects may be obtained easily even when a thickness of a lower buffer layer is not more than 200 nm. Therefore, a thickness of a lower buffer layer is preferably 200 nm or less.

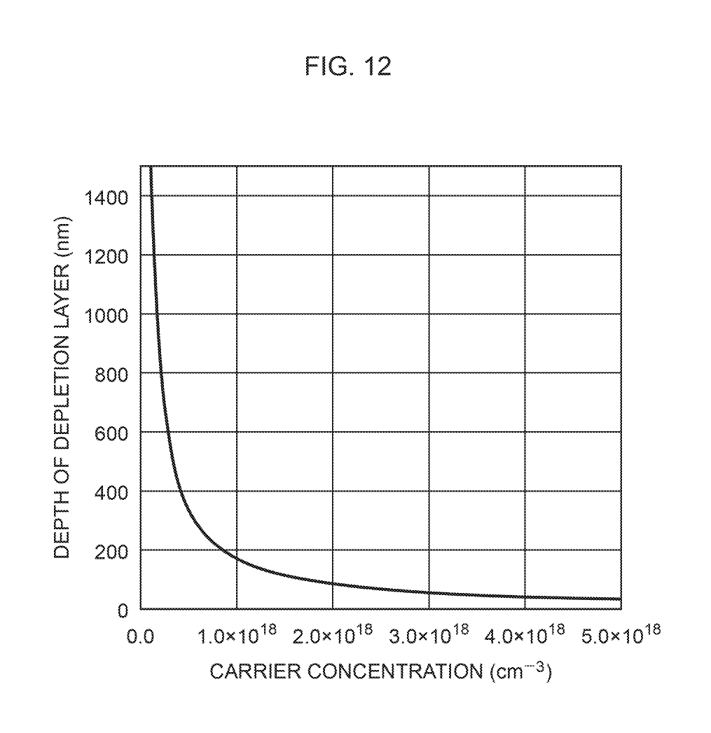

A lower buffer layer preferably has a thickness corresponding to a voltage applied to a drain electrode. FIG. 12 is a diagram illustrating a relation between a concentration of p-type carrier (positive hole) in the lower buffer layer 503 and a thickness of a depletion layer generated in the lower buffer layer 503 in the example illustrated in FIG. 5A. This diagram is derived from Poisson's equation (dE/dx=−ρ/ε), and is of a case where an electric field of 3.3 MV/cm is applied. A lower buffer layer is preferred to have a thickness larger than a thickness of a depletion layer obtained by such a manner.

An Element for an acceptor impurity or a donor impurity contained in a lower buffer layer is not limited in particular. Mg and Zn are exemplified as the acceptor impurity element, for example. Si, O, Ge, Te, and Se are exemplified as the donor impurity element, for example. A concentration of an acceptor impurity element or a donor impurity element is not limited in particular, and is preferred to be 1×10¹⁸ cm⁻³ or more and 1×10²¹ cm⁻³ or less. When a concentration of an impurity element is less than 1×10¹⁸ cm⁻³, there is a possibility that sufficient effects are not obtained. When a concentration of an impurity element is more than 1×10²¹ cm⁻³, there is a possibility that sufficient crystallinity is not obtained.

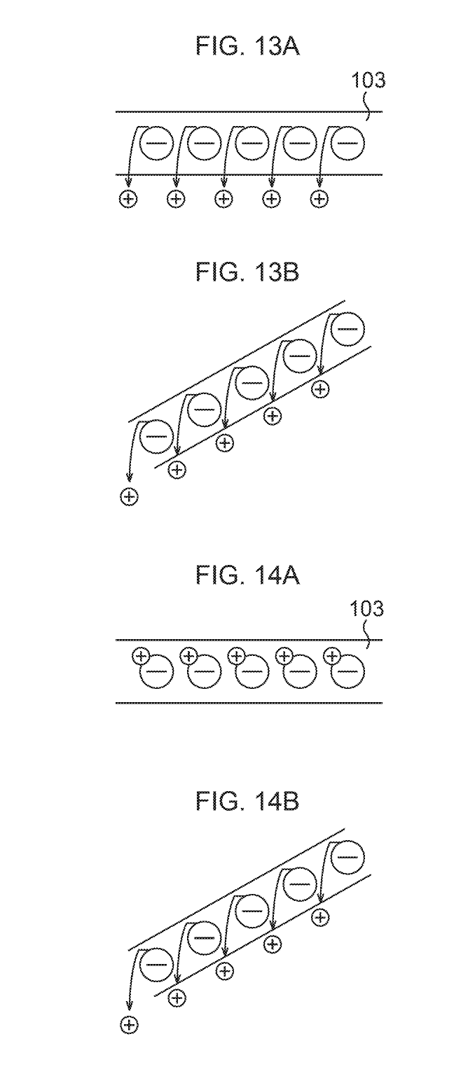

Whether an impurity contained in a lower buffer layer is an acceptor impurity elements or an donor impurity elements, it is preferred that the carrier concentration in the lower buffer layer is equal to or more than 1×10¹⁸ cm⁻³. When the carrier concentration is less than 1×10¹⁸ cm⁻³, there is a possibility that sufficient effects are not obtained. Change of carrier contained in a lower buffer layer will be explained. FIG. 13A and FIG. 13B are views illustrating change of carrier in a case where activation energy of impurity contained in a lower buffer layer is low, and FIG. 14A and FIG. 14B are views illustrating change of carrier in a case where activation energy of impurity contained in a lower buffer layer is high. Here, the case where activation energy of impurity is low refers to a case where the concentration of carriers activated at room temperature is less than 1×10¹⁸ cm⁻², and the case where activation energy of impurity is high refers to a case where the concentration of carriers activated at room temperature is equal to or more than 1×10¹⁸ cm⁻².

In the case where the activation energy of impurity contained in a lower buffer layer is low, carriers are released by heat energy even in thermal equilibrium, as illustrated in FIG. 13A. The heat energy is about 25 meV at room temperature. When a strong electric field is applied, not only carriers are released by the heat energy, but also carriers are released due to the influence of the strong electric field, as illustrated in FIG. 13B. As a result, a fixed charge is generated, the band of the nucleation layer changes as illustrated in FIG. 2, and a leak current can be suppressed.

On the other hand, in the case where the activation energy of impurity contained in a lower buffer layer is high, carriers are not released by heat energy of about 25 meV in thermal equilibrium, as illustrated in FIG. 14A. Therefore, a fixed charge is not generated, and the carrier concentration is low. However, when a strong electric field is applied, carriers are released due to the influence of the strong electric field, as illustrated in FIG. 14B. As a result, a fixed charge is generated, the band of the nucleation layer changes as illustrated in FIG. 2, and a leak current can be suppressed.

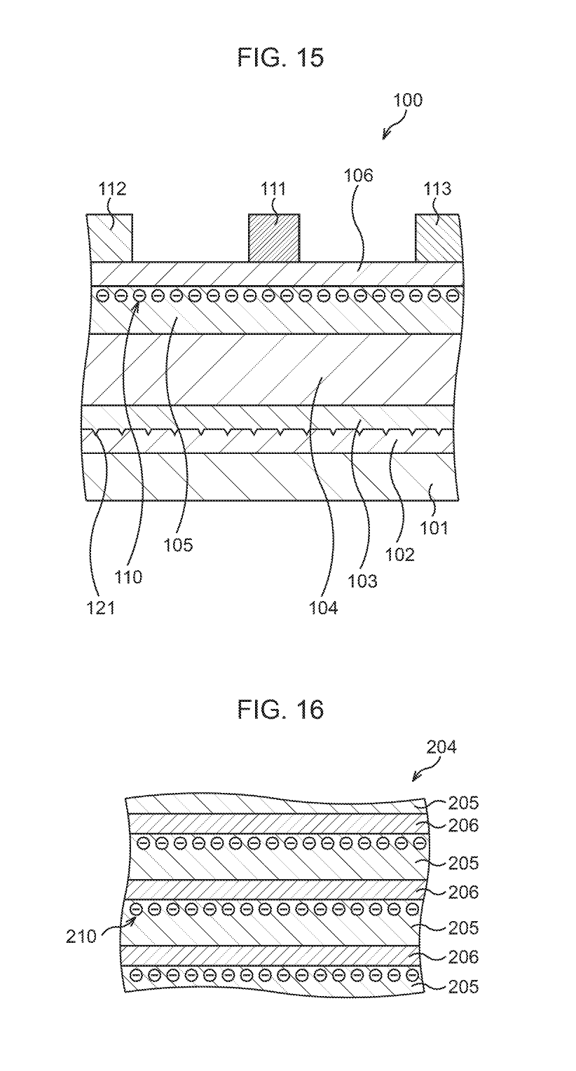

The nucleation layer 102 is preferably not intentionally doped with an impurity. When an impurity such as Si is doped in the nucleation layer 102, pits 121 are generated easily due to a difference in lattice constant, thermal expansion coefficient or the like from the substrate 101, as illustrated in FIG. 15. A crack may also occur in the nucleation layer 102. When the pits 121 or the like are generated, the nucleation layer 102 is thin in that portion, and thus the crystallinity of the lower buffer layer 103, the upper buffer layer 104 and so on thereabove may decrease or a crack may be generated. Further, it is not easy to form the nucleation layer 102 with excellent crystallinity while doping an impurity such as Si. For these reasons, the nucleation layer 102 is preferably not intentionally doped with an impurity.

The upper buffer layer 204 of superlattice structure is preferably not doped with an acceptor impurity element such as carbon. As illustrated in FIG. 16, the upper buffer layer 204 of the superlattice structure includes a GaN layer 205 and an AlN layer 206, and hence two-dimensional electron gas (2 DEG) 210 exists in the vicinity of the interface of the GaN layer 205 to the AlN layer 206. Thus, it is difficult to make the upper buffer layer 204 as a high-concentration p-type layer.

A layer may exist between the lower buffer layer and the nucleation layer, but preferably a lower surface of the lower buffer layer is in contact with an upper surface of the nucleation layer. This is because when a layer which is not particularly needed exists, this may lead to decrease in the thicknesses of the buffer layer, the carrier transit layer, and the carrier supply layer by the thickness of that layer, since the thicker the compound semiconductor layer is formed, the easier it can be cracked due to the influence of a lattice distortion or the like, as described above.

Although the Schottky gate structure is employed in the first to fourth embodiments, a structure in which a gate insulating film exists between the gate electrode and the carrier supply layer, that is, an MIS (metal insulator semiconductor) structure may be employed.

### Fifth Embodiment

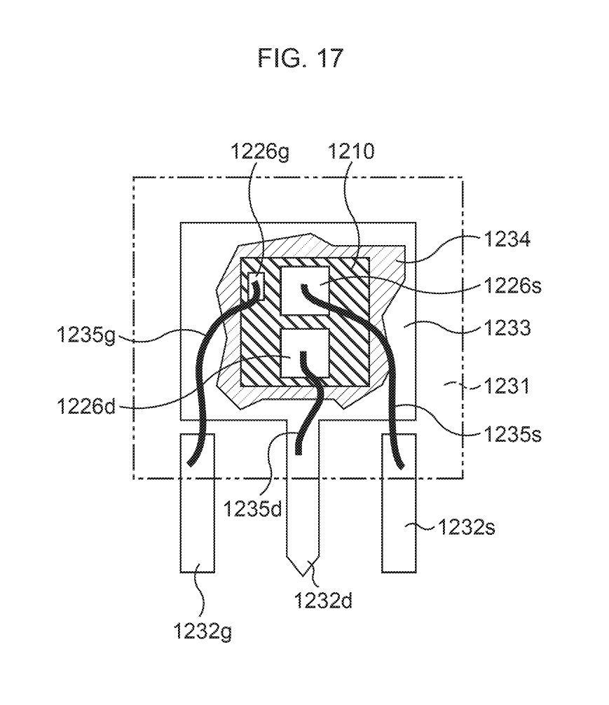

Next, a fifth embodiment is described. The fifth embodiment relates to a discrete package of a compound semiconductor device which includes a GaN-based HEMT. FIG. 17 is a view illustrating the discrete package according to the fifth embodiment.

In the fifth embodiment, as illustrated in FIG. 17, a back surface of a HEMT chip 1210 of the compound semiconductor device according to any one of the first to fourth embodiments is fixed on a land (die pad) 1233, using a die attaching agent 1234 such as solder. One end of a wire 1235d such as an Al wire is bonded to a drain pad 1226d, to which the drain electrode 113 is connected, and the other end of the wire 1235d is bonded to a drain lead 1232d integral with the land 1233. One end of a wire 1235s such as an Al wire is bonded to a source pad 1226s, to which the source electrode 112 is connected, and the other end of the wire 1235s is bonded to a source lead 1232s separated from the land 1233. One end of a wire 1235g such as an Al wire is bonded to a gate pad 1226g, to which the gate electrode 111 is connected, and the other end of the wire 1235g is bonded to a gate lead 1232g separated from the land 1233. The land 1233, the HEMT chip 1210 and so forth are packaged with a molding resin 1231, so as to project outwards a portion of the gate lead 1232g, a portion of the drain lead 1232d, and a portion of the source lead 1232s.

The discrete package may be manufactured by the procedures below, for example. First, the HEMT chip 1210 is bonded to the land 1233 of a lead frame, using a die attaching agent 1234 such as solder. Next, with the wires 1235g, 1235d and 1235s, the gate pad 1226g is connected to the gate lead 1232g of the lead frame, the drain pad 1226d is connected to the drain lead 1232d of the lead frame, and the source pad 1226s is connected to the source lead 1232s of the lead frame, respectively, by wire bonding. The molding with the molding resin 1231 is conducted by a transfer molding process. The lead frame is then cut away.

### Sixth Embodiment

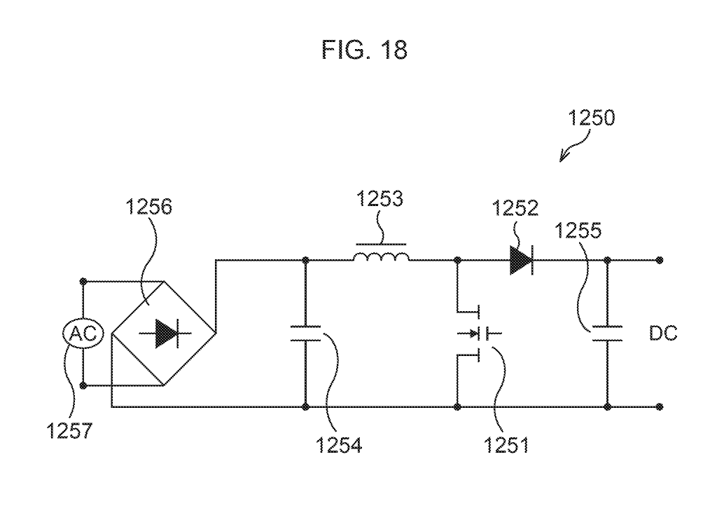

Next, a sixth embodiment is described. The sixth embodiment relates to a PFC (power factor correction) circuit equipped with a compound semiconductor device which includes a GaN-based HEMT. FIG. 18 is a wiring diagram illustrating the PFC circuit according to the sixth embodiment.

A PFC circuit 1250 has a switching element (transistor) 1251, a diode 1252, a choke coil 1253, capacitors 1254 and 1255, a diode bridge 1256, and an AC power source (AC) 1257. The drain electrode of the switching element 1251, the anode terminal of the diode 1252, and one terminal of the choke coil 1253 are connected with each other. The source electrode of the switching element 1251, one terminal of the capacitor 1254, and one terminal of the capacitor 1255 are connected with each other. The other terminal of the capacitor 1254 and the other terminal of the choke coil 1253 are connected with each other. The other terminal of the capacitor 1255 and the cathode terminal of the diode 1252 are connected with each other. A gate driver is connected to the gate electrode of the switching element 1251. The AC 1257 is connected between both terminals of the capacitor 1254 via the diode bridge 1256. A DC power source (DC) is connected between both terminals of the capacitor 1255. In the embodiment, the compound semiconductor device according to any one of the first to fourth embodiments is used as the switching element 1251.

In the method of manufacturing the PFC circuit 1250, for example, the switching element 1251 is connected to the diode 1252, the choke coil 1253 and so forth with solder, for example.

### Seventh Embodiment

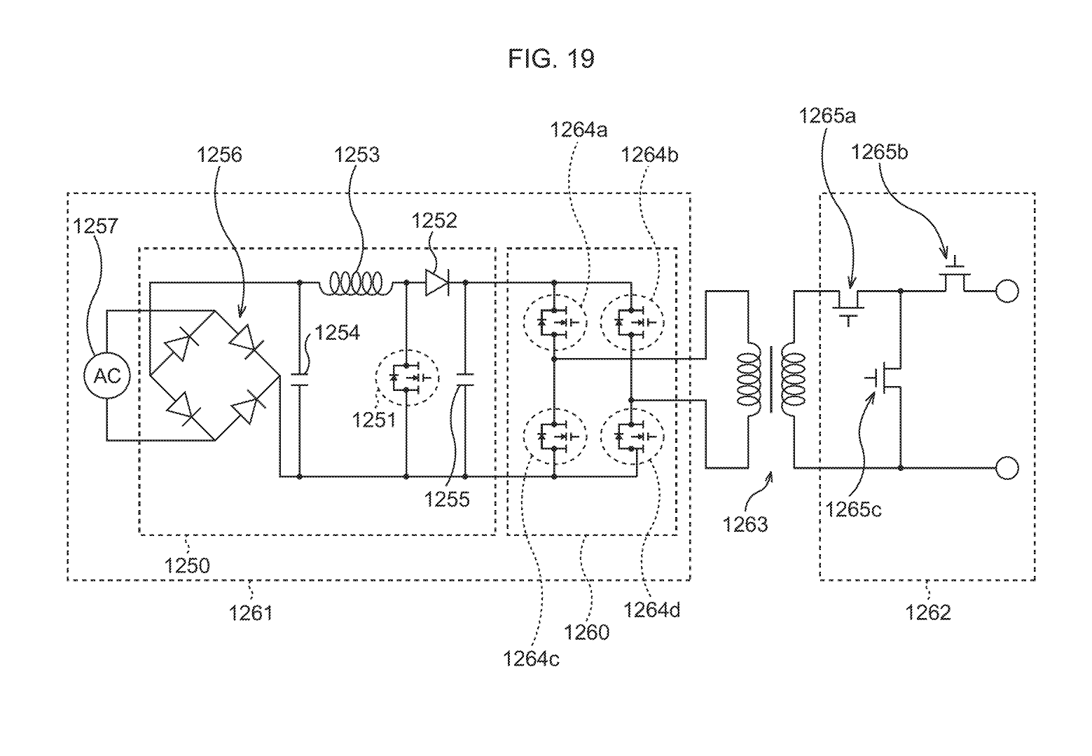

Next, a seventh embodiment is described. The seventh embodiment relates to a power supply apparatus equipped with a compound semiconductor device which includes a GaN-based HEMT. FIG. 19 is a wiring diagram illustrating the power supply apparatus according to the seventh embodiment.

The power supply apparatus includes a high-voltage, primary-side circuit 1261, a low-voltage, secondary-side circuit 1262, and a transformer 1263 arranged between the primary-side circuit 1261 and the secondary-side circuit 1262.

The primary-side circuit 1261 includes the PFC circuit 1250 according to the sixth embodiment, and an inverter circuit, which may be a full-bridge inverter circuit 1260, for example, connected between both terminals of the capacitor 1255 in the PFC circuit 1250. The full-bridge inverter circuit 1260 includes a plurality of (four, in the embodiment) switching elements 1264a, 1264b, 1264c and 1264d.

The secondary-side circuit 1262 includes a plurality of (three, in the embodiment) switching elements 1265a, 1265b and 1265c.

In the embodiment, the compound semiconductor device according to any one of first to fourth embodiments is used for the switching element 1251 of the PFC circuit 1250, and for the switching elements 1264a, 1264b, 1264c and 1264d of the full-bridge inverter circuit 1260. The PFC circuit 1250 and the full-bridge inverter circuit 1260 are components of the primary-side circuit 1261. On the other hand, a silicon-based general MIS-FET (field effect transistor) is used for the switching elements 1265a, 1265b and 1265c of the secondary-side circuit 1262.

### Eighth Embodiment

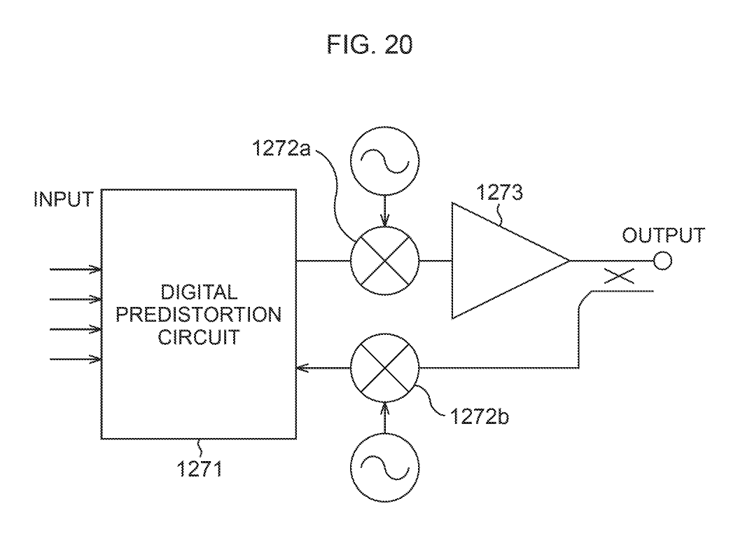

Next, an eighth embodiment is explained. The eighth embodiment relates to an amplifier equipped with the compound semiconductor device which includes a GaN-based HEMT. FIG. 20 is a wiring diagram illustrating the amplifier according to the eighth embodiment.

The amplifier includes a digital predistortion circuit 1271, mixers 1272a and 1272b, and a power amplifier 1273.

The digital predistortion circuit 1271 compensates non-linear distortion in input signals. The mixer 1272a mixes the input signal having the non-linear distortion already compensated, with an AC signal. The power amplifier 1273 includes the compound semiconductor device according to any one of the first to fourth embodiments, and amplifies the input signal mixed with the AC signal. In the embodiment, the signal on the output side may be mixed, upon switching, with an AC signal by the mixer 1272b, and may be sent back to the digital predistortion circuit 1271. The amplifier may be used as a high-frequency amplifier or a high-output amplifier.

In the above-described compound semiconductor device and the like, a leak current can be suppressed even when a high voltage is applied to a drain electrode because an appropriate second buffer layer is included.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device comprising:
a substrate;
a nucleation layer over the substrate;
a first buffer layer over the nucleation layer;
a second buffer layer between the nucleation layer and the first buffer layer, the second buffer layer containing an acceptor impurity element or a donor impurity element at a higher concentration than the first buffer layer;
a carrier transit layer in contact with the first buffer layer;
a carrier supply layer over the carrier transit layer; and
a gate electrode, a source electrode, and a drain electrode above the carrier supply layer.

2. The compound semiconductor device according to claim 1, wherein a lower surface of the second buffer layer is in contact with an upper surface of the nucleation layer.

3. The compound semiconductor device according to claim 1, wherein the acceptor impurity element is Mg or Zn or combination thereof.

4. The compound semiconductor device according to claim 1, wherein the donor impurity element is Si, O, Ge, Te, or Se or any combination thereof.

5. The compound semiconductor device according to claim 1, wherein a concentration of the acceptor impurity element or the donor impurity element in the second buffer layer is 1×10¹⁸ cm⁻³ or more and 1×10²¹ cm⁻³ or less.

6. The compound semiconductor device according to claim 1, wherein the substrate is a Si substrate, a SiC substrate, a sapphire substrate, a Ga₂O₃ substrate, or an AlN substrate.

7. The compound semiconductor device according to claim 1, wherein the nucleation layer is not intentionally doped with impurity.

8. The compound semiconductor device according to claim 1, wherein the second buffer layer is composed of a single layer.

9. A power supply apparatus, comprising a compound semiconductor device, wherein the compound semiconductor device comprises:
a substrate;
a nucleation layer over the substrate;
a first buffer layer over the nucleation layer;
a second buffer layer between the nucleation layer and the first buffer layer, the second buffer layer containing an acceptor impurity element or a donor impurity element at a higher concentration than the first buffer layer;
a carrier transit layer in contact with the first buffer layer;
a carrier supply layer over the carrier transit layer; and
a gate electrode, a source electrode, and a drain electrode above the carrier supply layer.

10. An amplifier, comprising a compound semiconductor device, wherein the compound semiconductor device comprises:
a substrate;
a nucleation layer over the substrate;
a first buffer layer over the nucleation layer;
a second buffer layer between the nucleation layer and the first buffer layer, the second buffer layer containing an acceptor impurity element or a donor impurity element at a higher concentration than the first buffer layer;
a carrier transit layer in contact with the first buffer layer;
a carrier supply layer over the carrier transit layer; and
a gate electrode, a source electrode, and a drain electrode above the carrier supply layer.

11. A method of manufacturing a compound semiconductor device comprising:
forming a nucleation layer over a substrate;
forming a first buffer layer over the nucleation layer;
forming a second buffer layer between the nucleation layer and the first buffer layer, the second buffer layer containing an acceptor impurity element or a donor impurity element at a higher concentration than the first buffer layer;
forming a carrier transit layer in contact with the first buffer layer;
forming a carrier supply layer over the carrier transit layer; and
forming a gate electrode, a source electrode, and a drain electrode above the carrier supply layer.

12. The method according to claim 11, wherein a lower surface of the second buffer layer is in contact with an upper surface of the nucleation layer.
